(19) United States
(12) Patent Application Publication
(10) Pub. No.: US 2025/0022787 A1
(43) Pub. Date: Jan. 16, 2025

(54) SEMICONDUCTOR PACKAGE

(71) Applicant: SAMSUNG ELECTRONICS CO., LTD., Suwon-si (KR)

(72) Inventors: Hyunsoo CHUNG, Suwon-si (KR); Kwang-Soo Kim, Suwon-si (KR); Jaesic Lee, Suwon-si (KR)

(73) Assignee: SAMSUNG ELECTRONICS CO., LTD., Suwon-si (KR)

(21) Appl. No.: 18/440,215

(22) Filed: Feb. 13, 2024

(30) Foreign Application Priority Data
Jul. 11, 2023 (KR) 10-2023-0090076

(51) Int. Cl. H01L 23/498; H01L 23/00; H01L 25/065

(52) U.S. Cl. CPC H01L 23/49838; H01L 23/49816; H01L 24/08; H01L 24/16; H01L 25/0655; H01L 2224/08146; H01L 2224/08155; H01L 2224/16146; H01L 2224/16225; H01L 2924/01013; H01L 2924/01029; H01L 2924/1431; H01L 2924/1434; H01L 2924/15311

(57) ABSTRACT

Disclosed is a semiconductor package comprising a first semiconductor chip, a second semiconductor chip, and a connection die. A hybrid bonding may be established between the connection die and the first semiconductor chip and between the connection die and the second semiconductor chip. The first semiconductor chip includes a first semiconductor substrate having first and second surfaces. The first surface is closer than the second surface to the connection die. The second semiconductor chip includes a second semiconductor substrate having third and fourth surfaces. The third surface is closer than the fourth surface to the connection die. The first and second semiconductor chips further include a power distribution wiring layer on the second surface of the first semiconductor chip and the fourth surface of the second semiconductor substrate.

### CROSS-REFERENCE TO RELATED APPLICATION

This U.S. nonprovisional application claims priority under 35 U.S.C § 119 to Korean Patent Application No. 10-2023-0090076 filed on Jul. 11, 2023 in the Korean Intellectual Property Office, the disclosure of which is hereby incorporated by reference in its entirety.

### BACKGROUND

### 1. Field

The disclosure relates to a semiconductor package.

### 2. Description of Related Art

A semiconductor package is provided to implement an integrated circuit chip to qualify for use in electronic products. A semiconductor package is typically configured such that a semiconductor chip is mounted on a printed circuit board and bonding wires or bumps are used to electrically connect the semiconductor chip to the printed circuit board. With the development of electronic industry, various studies have been conducted to improve reliability and durability of semiconductor packages.

### SUMMARY

The disclosure provides a semiconductor package having a reduced input/output (I/O) path between different kinds of logic chips electrically connected to each other.

According to an aspect of the disclosure, a semiconductor package includes: a first semiconductor chip; a second semiconductor chip spaced apart from the first semiconductor chip in a first direction; and a connection die on the first semiconductor chip and the second semiconductor chip, wherein a hybrid bonding is established between the connection die and the first semiconductor chip and between the connection die and the second semiconductor chip, wherein the first semiconductor chip includes a first semiconductor substrate including a first surface and a second surface, wherein the first surface and the second surface are on opposite sides of the first semiconductor substrate, and wherein the first surface is closer than the second surface to the connection die, wherein the second semiconductor chip includes a second semiconductor substrate having a third surface and a fourth surface, wherein the third surface and the fourth surface are on opposite sides of the second semiconductor substrate, and wherein the third surface is closer than the fourth surface to the connection die, and wherein the first semiconductor chip and the second semiconductor chip further include a power distribution wiring layer disposed on the second surface of the first semiconductor chip and the fourth surface of the second semiconductor substrate.

According to an aspect of the disclosure, a semiconductor package includes: a first semiconductor chip and a second semiconductor chip that are spaced apart from each other in a first direction; and a connection die disposed on the first semiconductor chip and the second semiconductor chip, wherein the first semiconductor chip includes: a first semiconductor substrate having a first surface and a second surface, wherein the first surface and the second surface are on opposites sides of the first semiconductor substrate, and wherein the first surface is closer than the second surface to the connection die; a first wiring layer disposed on the first surface; and a first through via that penetrates the first semiconductor substrate from the second surface toward the first surface, wherein the second semiconductor chip includes: a second semiconductor substrate having a third surface and a fourth surface, wherein the third surface and the fourth surface are on opposite sides of the second semiconductor substrate, and wherein the third surface is closer than the fourth surface to the connection die; a second wiring layer disposed on the third surface; and a second through via that penetrates the second semiconductor substrate from the fourth surface toward the third surface, wherein the first semiconductor chip and the second semiconductor chip further include a power distribution wiring layer disposed on the second surface of the first semiconductor substrate and the fourth surface of the second semiconductor substrate, and wherein the power distribution wiring layer includes: a common dielectric layer in contact with the second surface of the first semiconductor substrate and the fourth surface of the second semiconductor substrate; a first power distribution line connected to the first through via; and a second power distribution line connected to the second through via.

According to an aspect of the disclosure, a semiconductor package includes: a first semiconductor chip; a second semiconductor chip spaced apart in a first direction from the first semiconductor chip; a third semiconductor chip disposed on the first semiconductor chip; a plurality of fourth semiconductor chips stacked on the second semiconductor chip; and a connection die disposed on the first semiconductor chip and the second semiconductor chip, wherein the connection die is disposed between the third semiconductor chip and the plurality of fourth semiconductor chips, wherein a hybrid bonding is established between the first semiconductor chip and the second semiconductor chip, wherein the first semiconductor chip includes: a first semiconductor substrate including a first surface and a second surface, wherein the first surface and the second surface are on opposite sides of the first semiconductor substrate; a first circuit layer disposed on the first surface; a first signal wiring layer disposed on the first circuit layer; and a first through via that penetrates the first semiconductor substrate, wherein the second semiconductor chip includes: a second semiconductor substrate having a third surface and a fourth surface, wherein the third surface and the fourth surface are on opposite sides of the second semiconductor substrate; a second circuit layer disposed on the fourth surface; a second signal wiring layer disposed on the second circuit layer; and a second through via that penetrates the second semiconductor substrate, wherein the connection die includes: a third semiconductor substrate; and a third signal wiring layer disposed on the third semiconductor substrate, wherein the third signal wiring layer is in contact with the first signal wiring layer and the second signal wiring layer, and wherein the first semiconductor chip and the second semiconductor chip further include a power distribution wiring layer disposed on the second surface of the first semiconductor chip and the fourth surface of the second semiconductor substrate.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 illustrates a simplified plan view showing a semiconductor package according to one or more embodiments of the disclosure;

FIG. 2 illustrates a cross-sectional view taken along line I-I′ of FIG. 1;

FIG. 3A illustrates an enlarged view showing section aa of FIG. 2;

FIG. 3B illustrates an enlarged view showing section bb of FIG. 2;

FIG. 3C illustrates an enlarged view showing section cc of FIG. 2;

FIG. 4 illustrates a cross-sectional view showing a semiconductor package according to one or more embodiments of the disclosure;

FIG. 5 illustrates an enlarged view showing section aa of FIG. 4;

FIG. 6 illustrates a cross-sectional view showing a semiconductor package according to one or more embodiments of the disclosure;

FIGS. 7A, 8A, 9A, 10, 11A, 12A, 13A, 14, and 15 illustrate cross-sectional views showing a method of fabricating a semiconductor package according to one or more embodiments of the disclosure;

FIG. 7B illustrates an enlarged view showing section aa of FIG. 7A;

FIG. 7C illustrates an enlarged view showing section bb of FIG. 7A;

FIG. 7D illustrates an enlarged view showing section cc of FIG. 7A;

FIG. 8B illustrates an enlarged view showing section cc of FIG. 8A;

FIG. 9B illustrates an enlarged view showing section aa of FIG. 9A;

FIG. 9C illustrates an enlarged view showing section bb of FIG. 9A;

FIG. 9D illustrates an enlarged view showing section cc of FIG. 9A;

FIG. 11B illustrates an enlarged view showing section aa of FIG. 11A;

FIG. 11C illustrates an enlarged view showing section bb of FIG. 11A;

FIG. 11D illustrates an enlarged view showing section cc of FIG. 11A;

FIG. 12B illustrates an enlarged view showing section aa of FIG. 12A;

FIG. 12C illustrates an enlarged view showing section bb of FIG. 12A;

FIG. 12D illustrates an enlarged view showing section cc of FIG. 12A;

FIG. 13B illustrates an enlarged view showing section aa of FIG. 13A;

FIG. 13C illustrates an enlarged view showing section bb of FIG. 13A; and

FIG. 13D illustrates an enlarged view showing section cc of FIG. 13A.

### DETAILED DESCRIPTION

The following will now describe one or more embodiments of the disclosure in conjunction with the accompanying drawings.

In this description, the phrase “a certain component is connected or coupled to a different component” may be interpreted as that “the certain component is directly connected to the different component” or “an intervening element is present between the certain component and the different component.” The phrase “a certain component is in contact with a different component” may mean that “no intervening element is interposed between the certain component and the different component.”

Herein, the expression “at least one of a, b or c” indicates “only a,” “only b,” “only c,” “both a and b,” “both a and c,” “both b and c,” or “all of a, b, and c.”

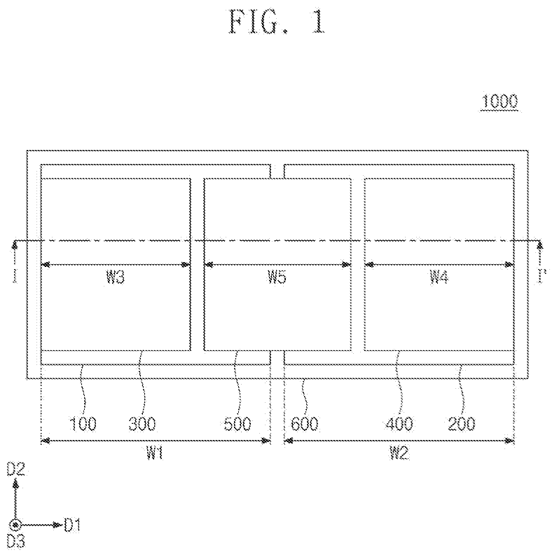

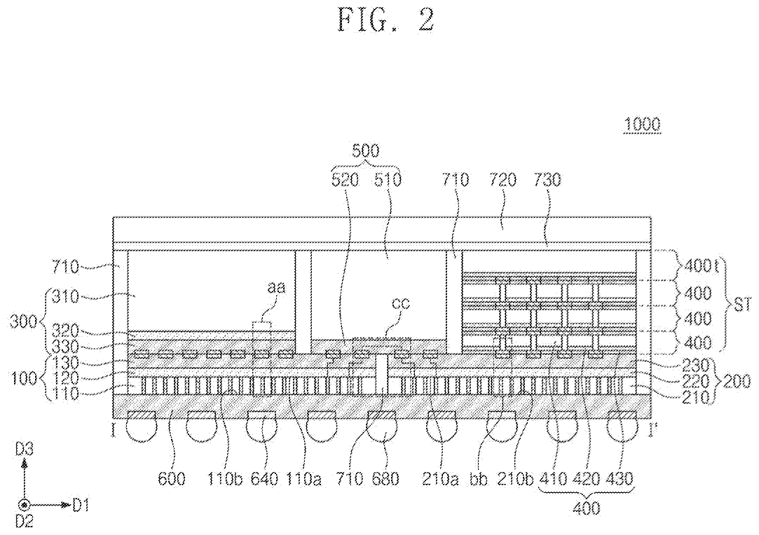

FIG. 1 illustrates a simplified plan view showing a semiconductor package according to one or more embodiments of the disclosure. FIG. 2 illustrates a cross-sectional view taken along line I-I′ of FIG. 1.

Referring to FIGS. 1 and 2, a semiconductor package 1000 may include a first semiconductor chip 100, a second semiconductor chip 200, a third semiconductor chip 300, a fourth semiconductor chip 400, and a connection die 500.

The first semiconductor chip 100 and the second semiconductor chip 200 may be a logic chip. For example, the first semiconductor chip 100 may be a logic chip such as an application specific integrated circuit (ASIC), a central processing unit (CPU), a graphic processing unit (GPU), and an application processor (AP), and the second semiconductor chip 200 may be a buffer chip of high bandwidth memory (HBM).

The third semiconductor chip 300 and the fourth semiconductor chip 400 may be one of a dummy chip and a memory chip. For example, the third semiconductor chip 300 may be a static random access memory (SRAM), and the fourth semiconductor chip 400 may be a dynamic random access memory (DRAM). Alternatively, the third semiconductor chip 300 may be a dummy chip, and the fourth semiconductor chip 400 may be a dynamic random access memory (DRAM). In this description, the connection die 500 may be called a bridge.

The first semiconductor chip 100 and the second semiconductor chip 200 may be spaced apart from each other in a first direction D1. The first semiconductor chip 100 and the second semiconductor chip 200 may include a power distribution wiring layer 600.

The third semiconductor chip 300 may be disposed on the first semiconductor chip 100. A hybrid bonding may be established between the first semiconductor chip 100 and the third semiconductor chip 300. A connection terminal, such as a solder ball, a bump, and a pillar, may not be interposed between the first semiconductor chip 100 and the third semiconductor chip 300. The third semiconductor chip 300 may vertically overlap the first semiconductor chip 100. A width W3 in the first direction D1 of the third semiconductor chip 300 may be less than a width W1 in the first direction D1 of the first semiconductor chip 100.

The fourth semiconductor chip 400 may be disposed on the second semiconductor chip 200. A hybrid bonding may be established between the fourth semiconductor chip 400 and the second semiconductor chip 200. A connection terminal, such as a solder ball, a bump, and a pillar, may not be interposed between the fourth semiconductor chip 400 and the second semiconductor chip 200. The fourth semiconductor chip 400 may vertically overlap the second semiconductor chip 200. The fourth semiconductor chip 400 may be spaced apart in the first direction D1 from the third semiconductor chip 300. A width W4 in the first direction D1 of the fourth semiconductor chip 400 may be less than a width W2 in the first direction D1 of the second semiconductor chip 200. For example, the fourth semiconductor chip 400 may be provided in plural. The fourth semiconductor chip 400 may form a chip stack structure ST. As discussed below, the fourth semiconductor chip 400 may include a through via 411. An uppermost one 400t of the fourth semiconductor chips 400 may not include a through via 411. According to one or more embodiments, differently from that shown, the uppermost fourth semiconductor chip 400t may include a through via 411.

The chip stack structure ST and the second semiconductor chip 200 may constitute a high bandwidth memory (HBM). The second semiconductor chip 200 may serve as a buffer chip. The fourth semiconductor chips 400 may be dynamic random access memories (DRAM) including the same memory circuit. A hybrid bonding may be accomplished between neighboring fourth semiconductor chips 400.

The connection die 500 may be disposed between the third semiconductor chip 300 and the fourth semiconductor chip 400. The connection die 500 may be disposed on the first semiconductor chip 100 and the second semiconductor chip 200. The connection die 500 may vertically overlap an edge of the first semiconductor chip 100 and an edge of the second semiconductor chip 200. A hybrid bonding may be established between the connection die 500 and the first semiconductor chip 100 and between the connection die 500 and the second semiconductor chip 200. A connection terminal, such as a solder ball, a bump, and a pillar, may not be interposed between the connection die 500 and the first semiconductor chip 100 and between the connection die 500 and the second semiconductor chip 200. A width W5 in the first direction D1 of the connection die 500 may be less than the width W1 in the first direction D1 of the first semiconductor chip 100 and the width W2 in the first direction D1 of the second semiconductor chip 200.

A dielectric structure 710 may fill a gap between the first semiconductor chip 100 and the second semiconductor chip 200, a gap between the third semiconductor chip 300 and the connection die 500, and a gap between the fourth semiconductor chip 400 and the connection die 500. The dielectric structure 710 may cover an exposed top surface of the power distribution wiring layer 600. The first semiconductor chip 100 may have a top surface exposed from the third semiconductor chip 300 to the connection die 500, and the dielectric structure 710 may cover the exposed top surface of the first semiconductor chip 100. The dielectric structure 710 may include a non-organic material. For example, the dielectric structure 710 may include silicon oxide (SiO₂).

A thermal radiation structure 720 may be disposed on the third semiconductor chip 300, the fourth semiconductor chip 400, the connection die 500, and the dielectric structure 710. The thermal radiation structure 720 may include, for example, silicon (Si). An adhesion pattern 730 may be interposed between the thermal radiation structure 720 and the third semiconductor chip 300, the fourth semiconductor chip 400, the connection die 500, and the dielectric structure 710. The adhesion pattern 730 may include a non-organic material. For example, the adhesion pattern 730 may include silicon oxide (SiO₂). According to one or more embodiments, the thermal radiation structure 720 may include metal.

As discussed below, the power distribution wiring layer 600 may include a common dielectric layer 610 and power distribution lines 620 disposed in the common dielectric layer 610. The power distribution wiring layer 600 may include at its lower portion a plurality of connection pads 640 connected to the power distribution lines 620. The connection pads 640 may include metal, such as aluminum or copper. Connection terminals 680 may be correspondingly disposed on the connection pads 640. Each of the connection terminals 680 may have a shape of one of pillars, bumps, and solder balls, and may include a conductive material such as solder.

The semiconductor package 1000 may be electrically connected through the connection terminals 680 to an external substrate such as a printed circuit board (PCB).

The first semiconductor chip 100 may include a first semiconductor substrate 110, a first circuit layer 120, a first signal wiring layer 130, a first through via 111, and the power distribution wiring layer 600. The second semiconductor chip 200 may include a second semiconductor substrate 210, a second circuit layer 220, a second signal wiring layer 230, a second through via 211, and the power distribution wiring layer 600.

The third semiconductor chip 300 may include a third semiconductor substrate 310, a third circuit layer 320, and a first unified wiring layer 330. The fourth semiconductor chip 400 may include a fourth semiconductor substrate 410, a fourth circuit layer 420, a third through via 411, and a second unified wiring layer 430. The connection die 500 may include a fifth semiconductor substrate 510 and a third signal wiring layer 520. In this description, a circuit layer may indicate a region or layer in which is formed an integrated circuit such as transistors. In this description, a front surface may mean one surface of a semiconductor substrate on which a circuit layer is disposed, and a rear surface may mean another surface of a semiconductor substrate which faces the one surface and on which no circuit layer is disposed.

The following will describe in detail a configuration of each of the first, second, third, and fourth semiconductor chips 100, 200, 300, and 400 and the connection die 500.

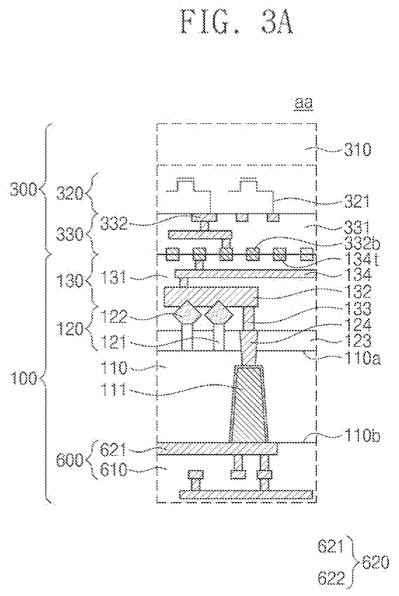

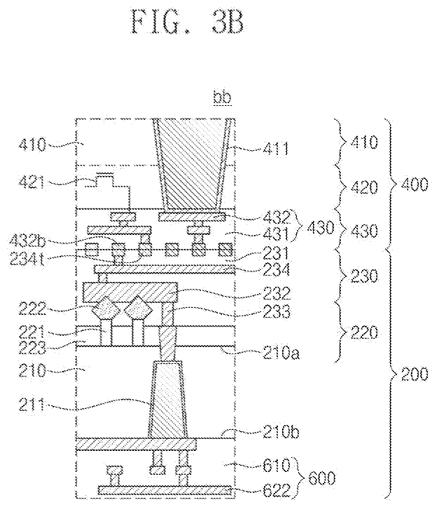

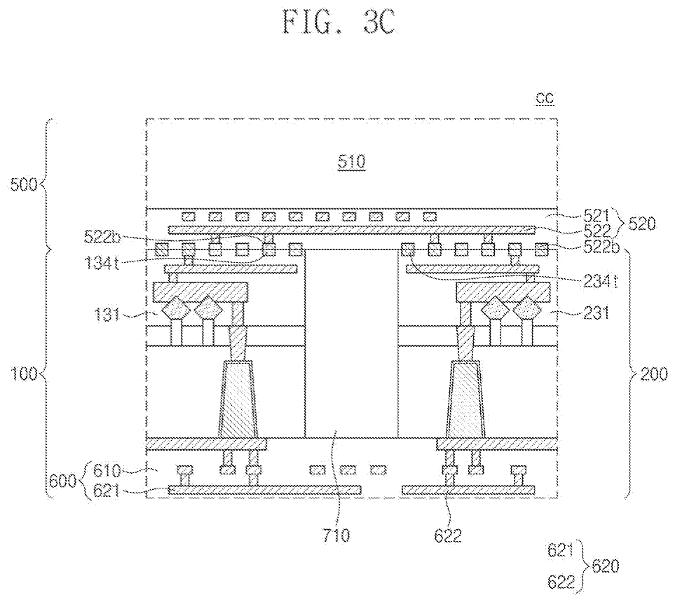

FIG. 3A illustrates an enlarged view showing section aa of FIG. 2. Referring to FIGS. 2 and 3A, the first semiconductor substrate 110 may be, for example, a silicon (Si) substrate. The first semiconductor substrate 110 may have a first surface 110a and a second surface 110b that is parallel to and opposite from the first surface 110a. The first surface 110a may be closer than the second surface 110b to the second semiconductor chip 200. The first surface 110a may be a surface on which the first circuit layer 120 is disposed. The first surface 110a may be a surface in contact with a bottom surface of a first device isolation layer 123 which will be discussed below.

The first circuit layer 120 may be disposed on the first surface 110a of the first semiconductor substrate 110. The first circuit layer 120 may include first fins 121 and first epitaxial patterns 122. A space between the first fins 121 may be filled with a first device isolation layer 123. Each of the first fins 121 may protrude from the first device isolation layer 123 and the first surface 110a of the first semiconductor substrate 110. The first fins 121 may respectively form channel structures of FinFETs, but the disclosure is not limited thereto. A subsequently described transistor of the first semiconductor chip 100 may be a single or combined FinFET, a nano-wire transistor, or a nano-sheet transistor. The first fins 121 may include, for example, silicon (Si). Each of the first epitaxial patterns 122 may include a semiconductor material, such as silicon (Si), germanium (Ge), or silicon-germanium (SiGe). The first device isolation layer 123 may include a dielectric material. The first device isolation layer 123 may include oxide, such as silicon oxide (SiO₂). The first epitaxial pattern 122 may include a first epitaxial contact 132 which will be discussed below, thereby constituting a transistor.

A buried first power rail 124 may be provided on the first semiconductor substrate 110. The buried first power rail 124 may penetrate the first device isolation layer 123 and may be buried in an upper portion of the first semiconductor substrate 110, which upper portion is adjacent to the first surface 110a. According to one or more embodiments, the buried first power rail 124 may protrude onto a top surface of the first device isolation layer 123. The buried first power rail 124 may have a top surface lower than a bottom surface of the first device isolation layer 123. The buried first power rail 124 may include metal, such as copper (Cu), cobalt (Co), tungsten (W), and ruthenium (Ru).

The first signal wiring layer 130 may be disposed on the first circuit layer 120. The first signal wiring layer 130 may include a first upper dielectric layer 131, and may also include a first epitaxial contact 132, a first vertical contact 133, and a first signal line 134 that are provided in the first upper dielectric layer 131.

The first upper dielectric layer 131 may include a dielectric material such as oxide (e.g., SiO₂). An invisible interface may be provided between the first upper dielectric layer 131 and the first device isolation layer 123.

The first epitaxial contact 132 may be disposed on the first epitaxial pattern 122. The first epitaxial contact 132 may be a metal layer that extends along the first direction D1 or a second direction D2 and is in contact with the first epitaxial contact 132. In this description, the second direction D2 may indicate a direction orthogonal to the first direction D1. A third direction D3 may denote a direction perpendicular to the first direction D1 and the second direction D2.

The first vertical contact 133 may be disposed between and connect the first epitaxial contact 132 and the buried first power rail 124. The first vertical contact 133 may be a via that extends along the third direction D3 from the first epitaxial contact 132.

A plurality of first signal lines 134 may be disposed on the first epitaxial contact 132. The first signal line 134 may include metal, such as copper and aluminum. The plurality of first signal lines 134 may be constituted to route signals.

The first epitaxial pattern 122 may include a power tapping epitaxial pattern that is a power supply connector and a non-power tapping epitaxial pattern that is not a power supply connector. The first signal lines 134 may be connected to the non-power tapping epitaxial pattern so as to route signals between transistors. First power distribution lines 621 which will be discussed below may be connected to the power tapping epitaxial pattern, and may not be connected to the first signal lines 134.

The first through via 111 may extend along the third direction D3, or from the second surface 110b toward the first surface 110a of the first semiconductor substrate 110. The first through via 111 may include a barrier pattern and a conductive pattern on the barrier pattern. The barrier pattern may include at least one selected from WN, TIN, TiSN, WSiN, and RuTiN. The conductive pattern may include at least one selected from tungsten (W), copper (Cu), polysilicon, and aluminum (Al). The first through via 111 may be in contact with the buried first power rail 124.

The power distribution wiring layer 600 may be disposed on the second surface 110b of the first semiconductor substrate 110. The common dielectric layer 610 may include a non-organic dielectric material, such as silicon oxide. The common dielectric layer 610 may be in contact with the second surface 110b of the first semiconductor substrate 110. The power distribution lines 620 may include first power distribution lines 621 and second power distribution lines 622. The first power distribution lines 621 may be electrically connected to the first through via 111. The second power distribution lines 622 may not be electrically connected to the first through via 111. As discussed below, the second power distribution lines 622 may be electrically connected to the second through via 211. The power distribution lines 620 may include metal, such as aluminum or copper.

The third semiconductor chip 300 may be disposed on the first signal wiring layer 130. The third semiconductor substrate 310 may include silicon, and may have a thickness greater than that of the first semiconductor substrate 110.

The third circuit layer 320 may be disposed on one surface of the third semiconductor substrate 310, which one surface is adjacent to the first semiconductor substrate 110. The third circuit layer 320 may include a first integrated circuit 321 such as a transistor. For example, the first integrated circuit 321 may be a circuit that constitutes a static random access memory (SRAM).

The first unified wiring layer 330 may be disposed on the third circuit layer 320. The first unified wiring layer 330 may include a first lower dielectric layer 331 and first unified lines 332. The first unified lines 332 may include signal lines and power distribution lines. The first unified lines 332 may be provided in the first lower dielectric layer 331. The first unified lines 332 may include metal, such as aluminum or copper. The first lower dielectric layer 331 may include a non-organic dielectric material, such as silicon oxide.

Lowermost ones 332b of the first unified lines 332 may be in contact with uppermost ones 134t of the first signal lines 134. According to one or more embodiments, an invisible interface may be provided between the first unified line 332b and the first signal line 134t that are in contact with each other. A connection terminal, such as a solder ball, a bump, and a pillar, may not be interposed between the first unified line 332b and the first signal line 134t that are in contact with each other. The first upper dielectric layer 131 and the first lower dielectric layer 331 may be in contact with each other. According to one or more embodiments, an invisible interface may be provided between the first upper dielectric layer 131 and the first lower dielectric layer 331.

FIG. 3B illustrates an enlarged view showing section bb of FIG. 2. Referring to FIGS. 2 and 3B, the second semiconductor substrate 210, the second circuit layer 220, the second signal wiring layer 230, the second through via 211, and the second lower wiring layer 240 may respectively correspond to the first semiconductor substrate 110, the first circuit layer 120, the first signal wiring layer 130, the first through via 111, and the first lower wiring layer 140. In this description, the phrase “correspond to” may mean that corresponding components have the same function, have the same connection relationship, have similar shapes, or include the same or similar materials.

The second semiconductor chip 200 may be a buffer chip. The second semiconductor substrate 210 may have a third surface 210a and a fourth surface 210b that is parallel to and opposite from the third surface 210a. The third surface 210a may be closer than the fourth surface 210b to the fourth semiconductor chip 400. The third surface 210a may be a surface on which the second circuit layer 220 is disposed. The third surface 210a may be a surface in contact with a bottom surface of a second device isolation layer 223 which will be discussed below.

The second circuit layer 220 may include second fins 221 and second epitaxial patterns 222. A space between the second fins 221 may be filled with a second device isolation layer 223. The second fins 221, the second epitaxial pattern 222, and the second device isolation layer 223 may respectively correspond to the first fins 121, the first epitaxial pattern 122, and the first device isolation layer 123. The second circuit layer 220 may include, for example, a memory controller circuit.

A buried second power rail 224 may be provided on the second semiconductor substrate 210. The buried second power rail 224 may correspond to the buried first power rail 124.

The second signal wiring layer 230 may be disposed on the second circuit layer 220. The second signal wiring layer 230 may include a second upper dielectric layer 231, and may also include a second epitaxial contact 232, a second vertical contact 233, and a second signal line 234 that are provided in the second upper dielectric layer 231. The second upper dielectric layer 231, the second epitaxial contact 232, the second vertical contact 233, and the second signal line 234 may respectively correspond to the first upper dielectric layer 131, the first epitaxial contact 132, the first vertical contact 133, and the first signal line 134.

The power distribution wiring layer 600 may be disposed on the fourth surface 210b of the second semiconductor substrate 210. The common dielectric layer 610 may be in contact with the fourth surface 210b of the second semiconductor substrate 210. The second power distribution lines 622 may be electrically connected to the second through via 211 and may not be electrically connected to the first through via 111.

The fourth semiconductor chip 400 may be disposed on the second signal wiring layer 230.

The fourth semiconductor substrate 410 may include silicon, and the fourth circuit layer 420 may be disposed on one surface of the fourth semiconductor substrate 410, which one surface is adjacent to the second semiconductor substrate 210. The fourth circuit layer 420 may include a second integrated circuit 421 including a transistor and a capacitor. The second integrated circuit 421 may include a plurality of memory cells that are arranged in a grid shape.

The second unified wiring layer 430 may be disposed on the fourth circuit layer 420. The second unified wiring layer 430 may include a second lower dielectric layer 431 and second unified lines 432. The second unified lines 432 may include signal lines and power distribution lines. The second unified lines 432 may be provided in the second lower dielectric layer 431. The second unified lines 432 may include metal, such as aluminum or copper. The second lower dielectric layer 431 may include a non-organic dielectric material, such as silicon oxide.

Lowermost ones 432b of the second unified lines 432 may be in contact with uppermost ones 234t of the second signal lines 234. According to one or more embodiments, an invisible interface may be provided between the second unified line 432b and the second signal line 234t that are in contact with each other. A connection terminal, such as a solder ball, a bump, and a pillar, may not be interposed between the second unified line 432b and the second signal line 234t. The second upper dielectric layer 231 and the second lower dielectric layer 431 may be in contact with each other. According to one or more embodiments, an invisible interface may be provided between the second upper dielectric layer 231 and the second lower dielectric layer 431.

The third through via 411 may penetrate the fourth semiconductor substrate 410 to come into connection with the second unified line 432. The third through via 411 may include a barrier pattern and a conductive pattern on the barrier pattern.

Referring to FIGS. 2 and 3C, the connection die 500 may connect the first semiconductor chip 100 and the second semiconductor chip 200 to each other.

The fifth semiconductor substrate 510 may be, for example, a silicon substrate. The third signal wiring layer 520 may be disposed on one surface of the fifth semiconductor substrate 510, which one surface is adjacent to the first semiconductor chip 100 and the second semiconductor chip 200. The connection die 500 may not include an integrated circuit such as a transistor. The connection die 500 may not include a circuit layer.

The third signal wiring layer 520 may include a third lower dielectric layer 521 and third signal lines 522 provided in the third lower dielectric layer 521. The third lower dielectric layer 521 may include a non-organic dielectric material, such as silicon oxide. The third signal lines 522 may include a metallic material, such as copper and aluminum.

A lowermost third signal line 522b of the third signal lines 522 may be in contact with an uppermost one 134t of the first signal lines 134 and an uppermost one 234t of the second signal lines 234. An invisible interface may be provided between the third signal line 522b and the first signal line 134t that are in contact with each other and between the third signal line 522b and the second signal line 234t that are in contact with each other. An invisible interface may be provided between the third lower dielectric layer 521 and the first upper dielectric layer 131 that are in contact with each other and between the third lower dielectric layer 521 and the second upper dielectric layer 231 that are in contact with each other.

A dielectric structure 710 may be interposed between the first semiconductor substrate 110 and the second semiconductor substrate 210, between the first circuit layer 120 and the second circuit layer 220, and between the first signal wiring layer 130 and the second signal wiring layer 230. The dielectric structure 710 may be disposed on the power distribution wiring layer 600 and in contact with the top surface of the power distribution wiring layer 600.

According to the disclosure, each of the first semiconductor chip 100 and the second semiconductor chip 200 may have a backside power distribution network (BSPDN) structure in which the power distribution wiring layer 600 is disposed on a rear surface thereof. On front surfaces of the first semiconductor chip 100 and the second semiconductor chip 200, the connection die 500 may transfer signals between the first semiconductor chip 100 and the second semiconductor chip 200. For example, input/output signals may move through the connection die 500.

In a semiconductor package according to a comparative example, each of a first semiconductor chip and a second semiconductor chip may have a front power distribution network structure. In addition, the first semiconductor chip and the second semiconductor chip may be connected through an interposer. For example, first power distribution lines may be omitted on a rear surface of the first semiconductor chip, and may be disposed on a front surface of the first semiconductor chip. In this configuration, the first power distribution lines and first signal lines may be disposed on a first circuit layer. Likewise, second power distribution lines may be omitted on a rear surface of the second semiconductor chip, and may be disposed on a front surface of the second semiconductor chip. In this configuration, the second power distribution lines and second signal lines may be disposed on a second circuit layer. To prevent entanglement between the first signal lines and the first power distribution lines, a path between the first signal lines of the comparative example may be longer than that according to one or more embodiments. To prevent entanglement between the second signal lines and the second power distribution lines, a path between the second signal lines according to the comparative example may be longer than that according to one or more embodiments. For example, a semiconductor package according to one or more embodiments may have reduced lengths of transfer paths when input/output (I/O) signals are transferred, and thus may have increased performance.

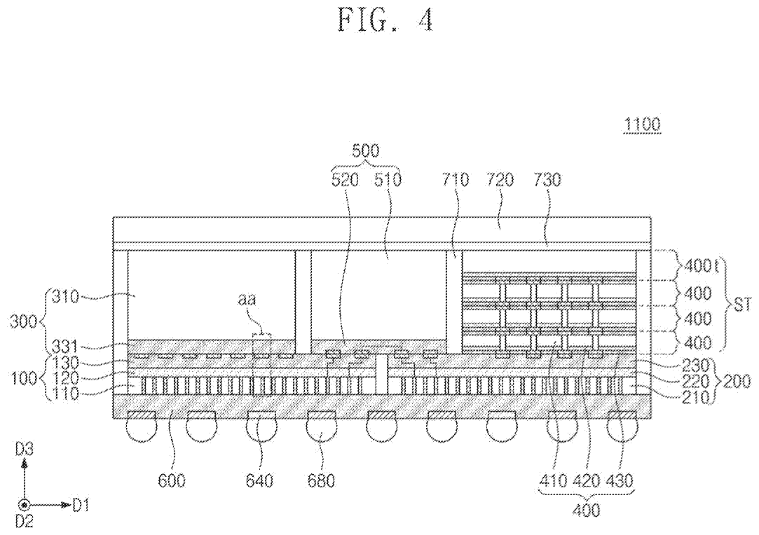

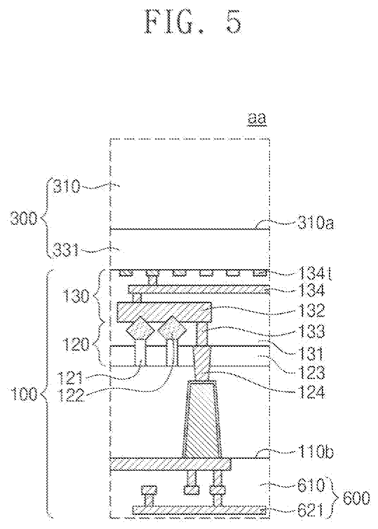

FIG. 4 illustrates a cross-sectional view showing a semiconductor package according to one or more embodiments of the disclosure. FIG. 5 illustrates an enlarged view showing section aa of FIG. 4. Omission will be made to avoid those features discussed with reference to FIGS. 1, 2, 3A, 3B, and 3C, except the following discussion.

Referring to FIGS. 4 and 5, in a semiconductor package 1100 according to one or more embodiments, the third semiconductor chip 300 may be a dummy chip. For example, the third semiconductor chip 300 may not include the third circuit layer 320. No integrated circuit may be disposed on the third semiconductor substrate 310. One surface 310a of the third semiconductor substrate 310 may be in contact with the first lower dielectric layer 331. The first unified lines 332 may not be provided in the first lower dielectric layer 331. According to one or more embodiments, differently from that shown, dummy lines may be provided in the first lower dielectric layer 331.

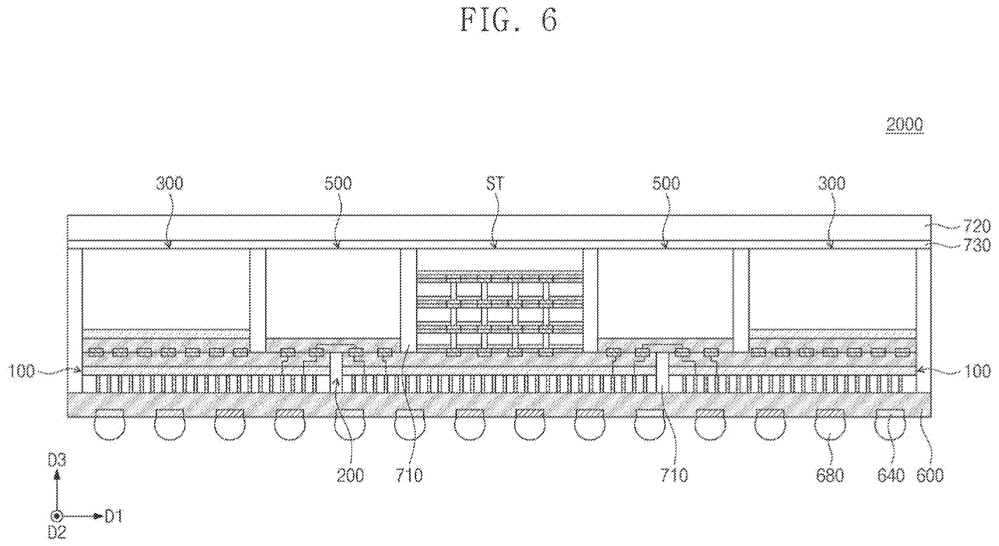

FIG. 6 illustrates a cross-sectional view showing a semiconductor package according to one or more embodiments of the disclosure. A repetitive explanation will be omitted except the following discussion.

Referring to FIG. 6, there may be provided a semiconductor package 2000 according to one or more embodiments. The semiconductor package 2000 may include a plurality of first semiconductor chips 100. For example, a pair of first semiconductor chips 100 may be spaced apart from each other in the first direction D1. A second semiconductor chip 200 may be disposed between the first semiconductor chip 100.

A plurality of third semiconductor chips 300 may be correspondingly disposed on the first semiconductor chips 100. A connection die 500 may be provided in plural. For example, two connection dies 500 may connect one first semiconductor chip 100 disposed on one side and another first semiconductor chip 100 disposed on another side to the second semiconductor chip 200 interposed between the one first semiconductor chip 100 and the another first semiconductor chip 100.

Differently from that shown, the semiconductor package 2000 may include a plurality of second semiconductor chips 200. Differently from that shown, the semiconductor package 2000 may include a plurality of first semiconductor chips 100 and a plurality of second semiconductor chips 200. When each of the first semiconductor chip 100 and the second semiconductor chip 200 is provided in plural, the connection die 500 may also be provided in plural and may connect the first semiconductor chip 100 and the second semiconductor chip 200 to each other.

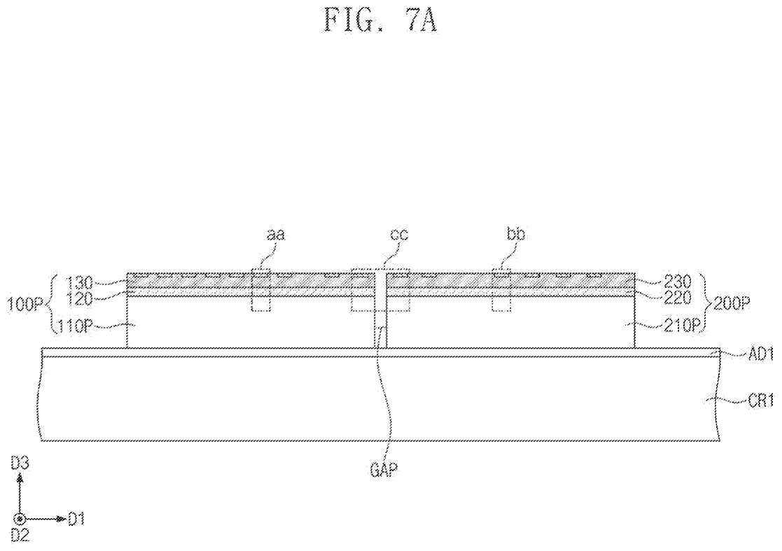

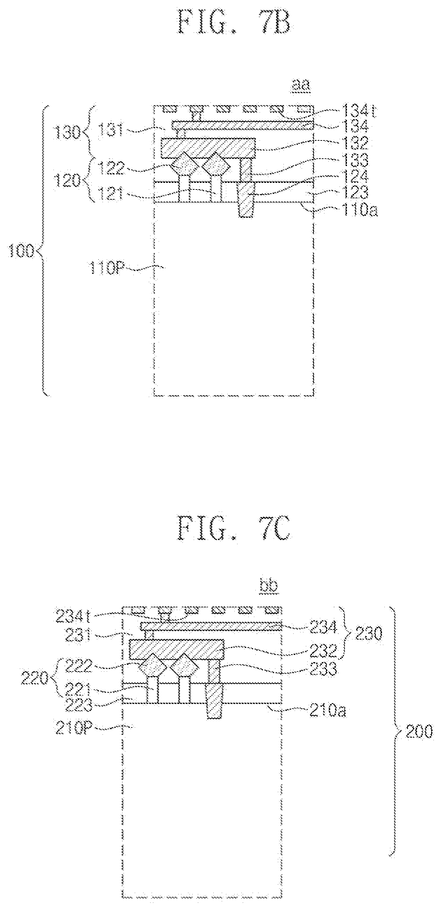

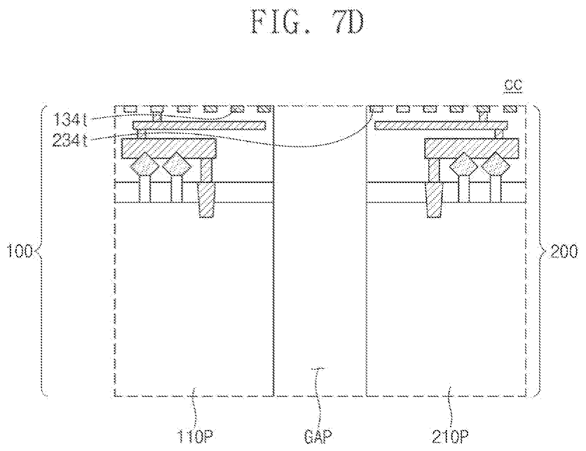

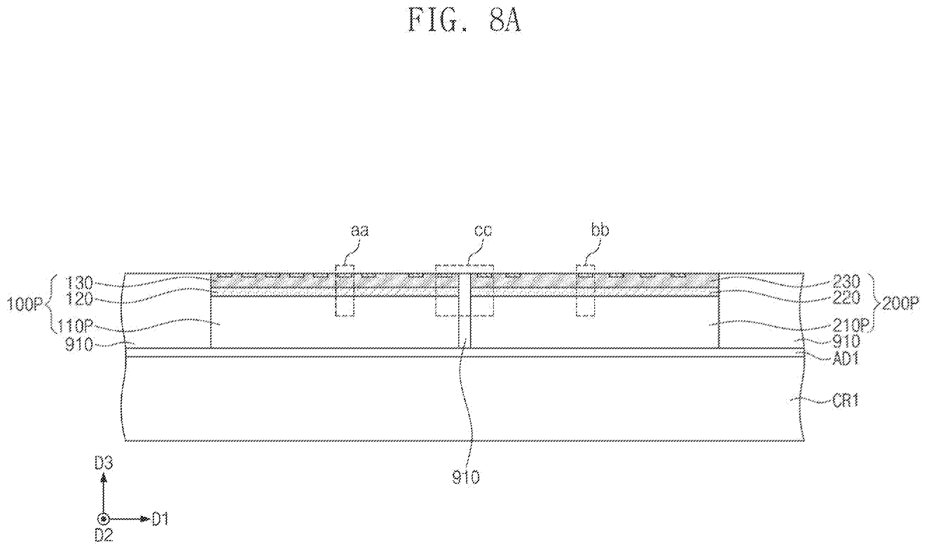

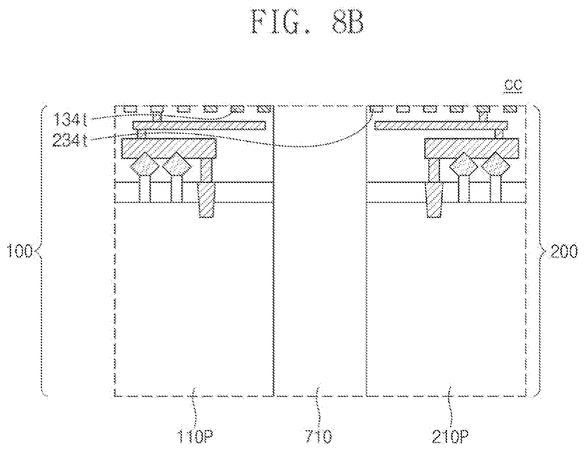

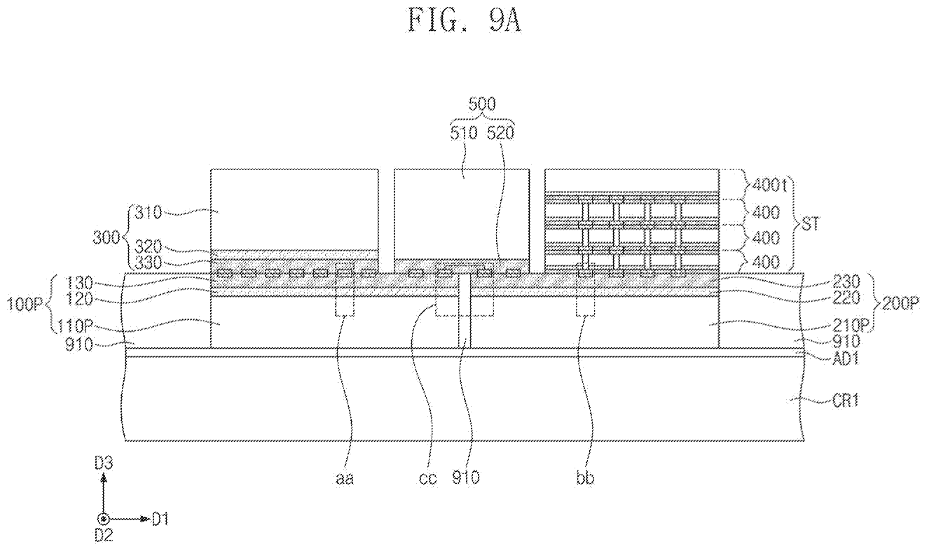

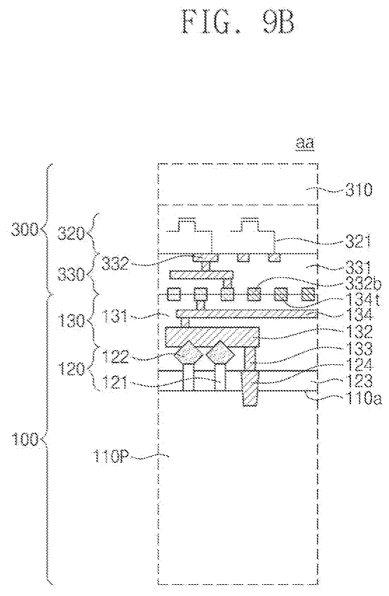

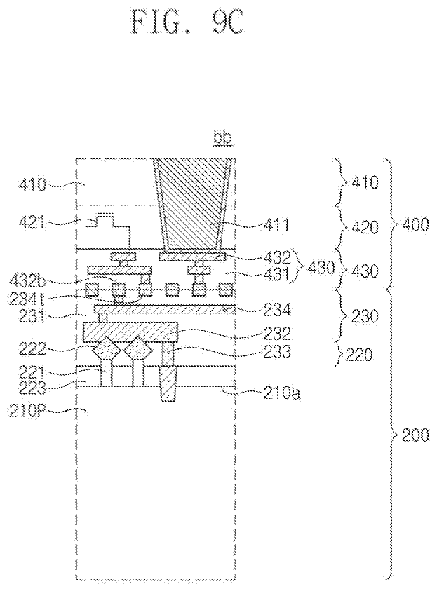

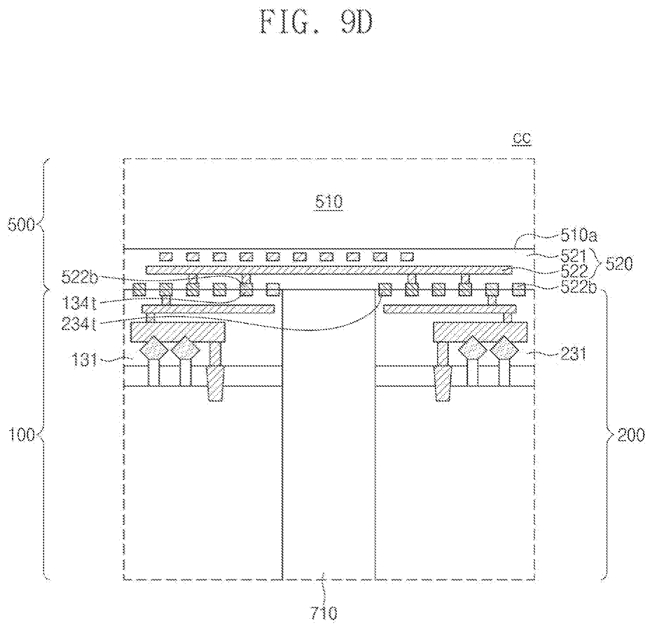

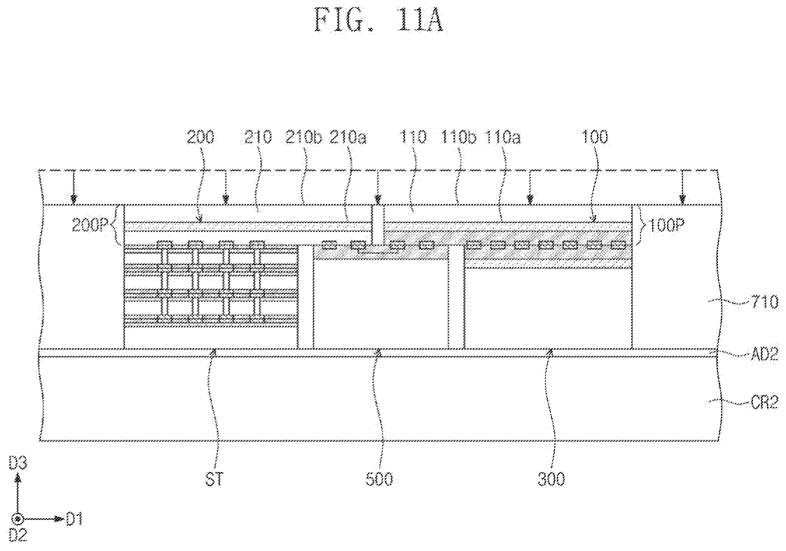

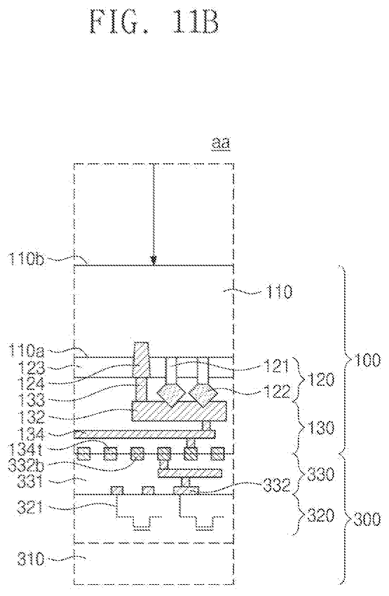

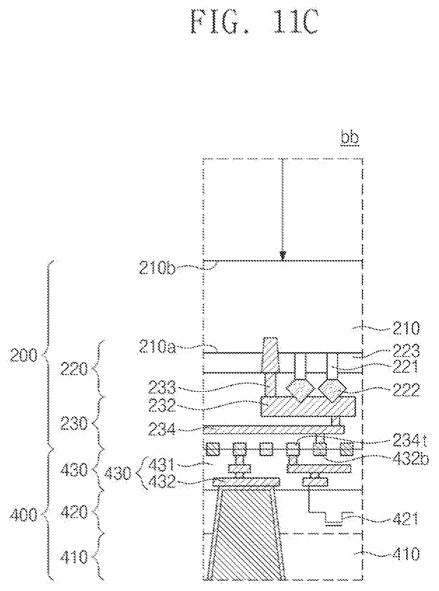

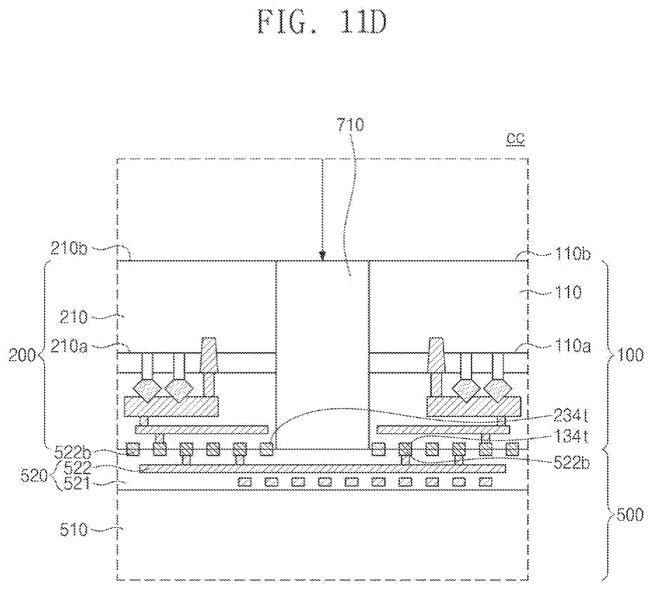

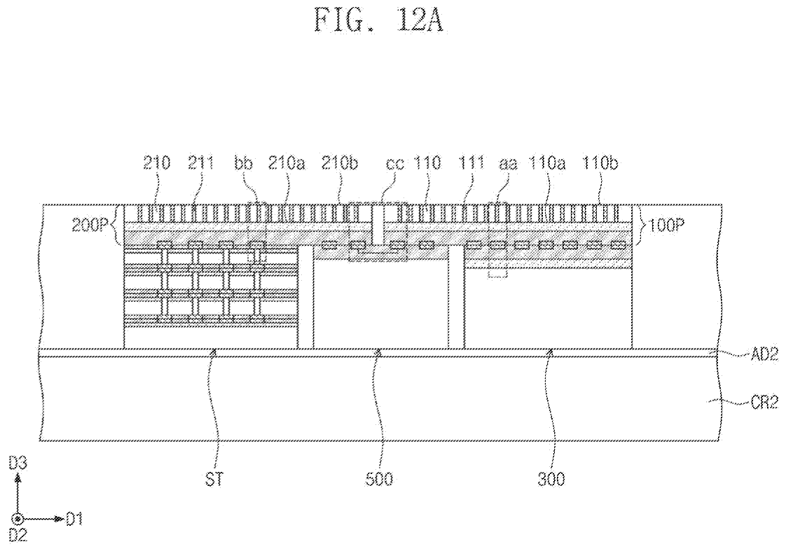

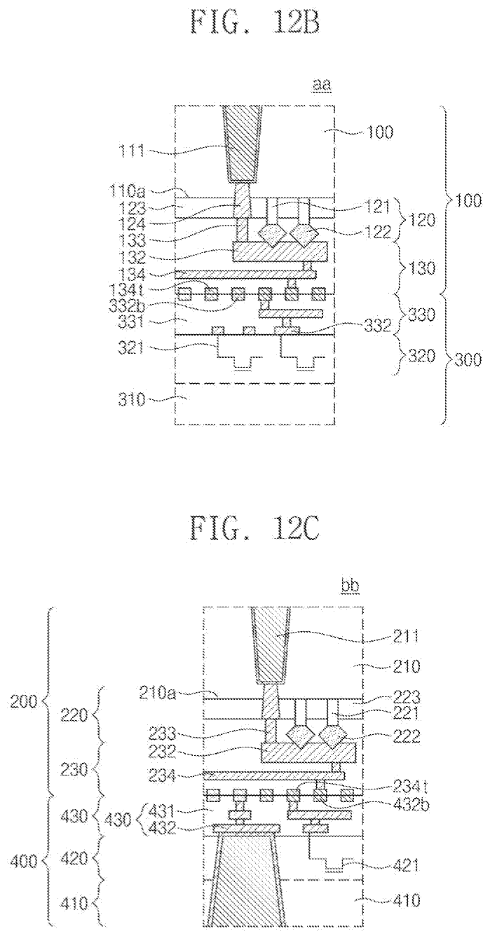

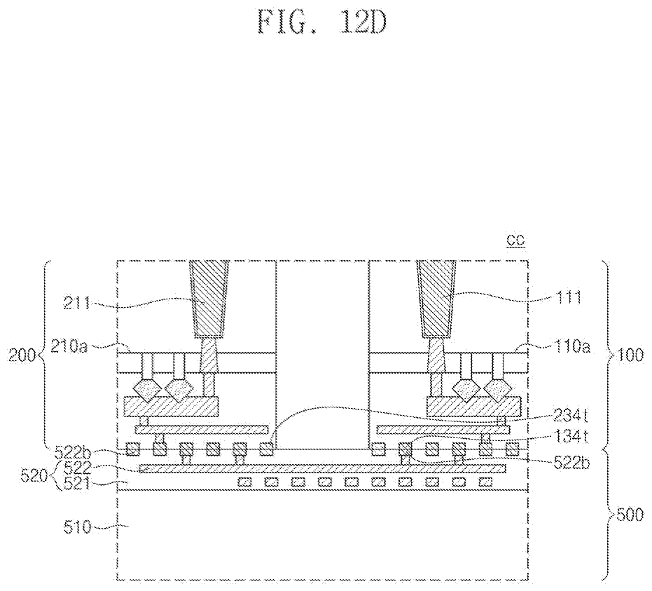

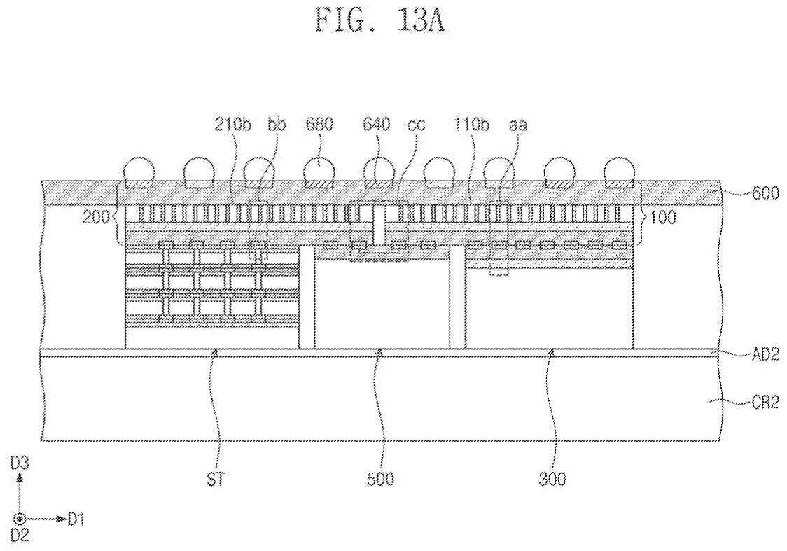

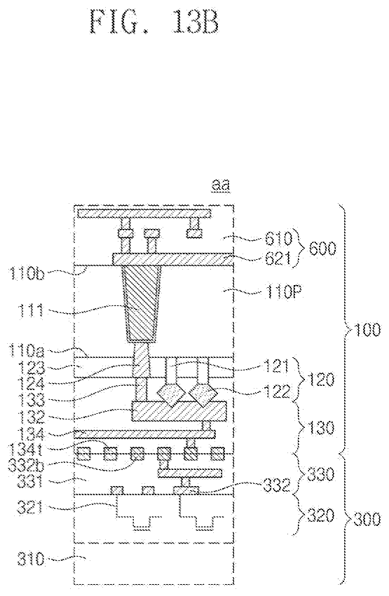

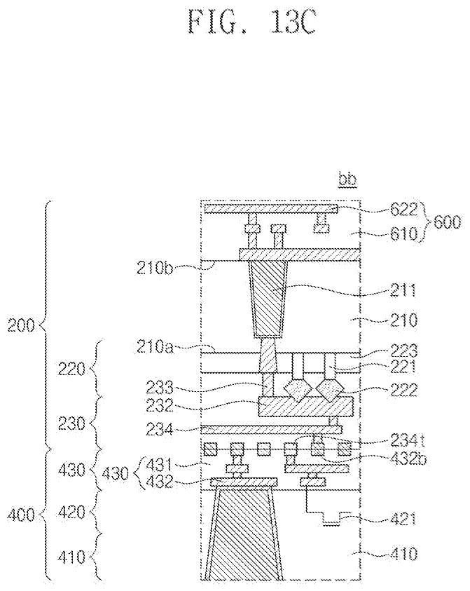

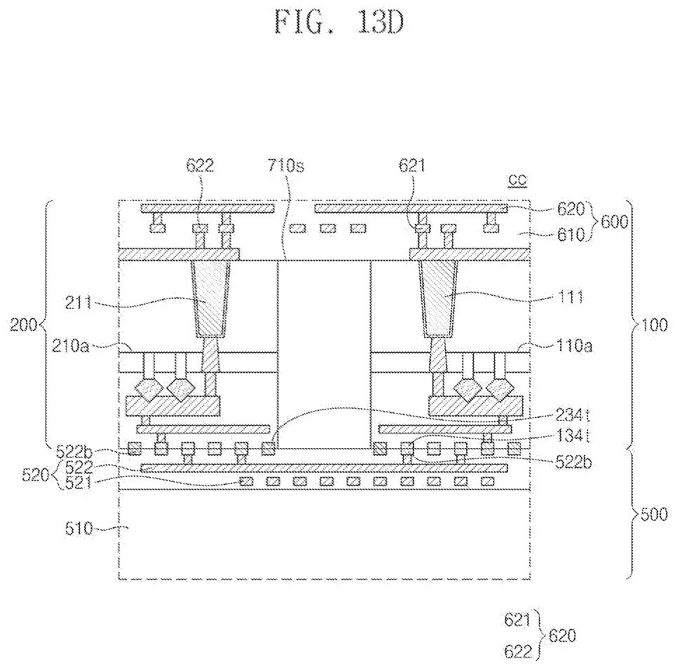

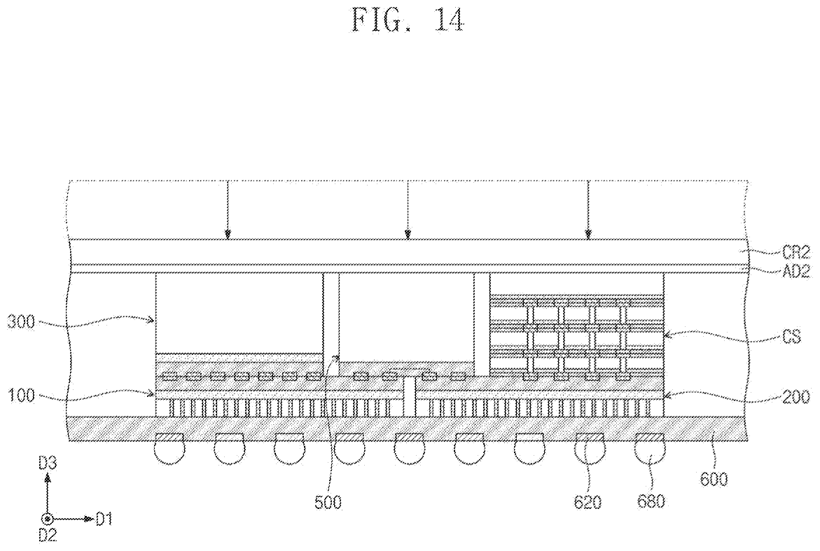

FIGS. 7A, 8A, 9A, 10, 11A, 12A, 13A, 14, and 15 illustrate cross-sectional views showing a method of fabricating a semiconductor package according to one or more embodiments of the disclosure. FIGS. 7B, 7C, and 7D illustrate enlarged views respectively showing sections aa, bb, and cc of FIG. 7A. FIG. 8B illustrates an enlarged view showing section cc of FIG. 8A. FIGS. 9B, 9C, and 9D illustrate enlarged views respectively showing sections aa, bb, and cc of FIG. 9A. FIGS. 11B, 11C, and 11D illustrate enlarged views respectively showing sections aa, bb, and cc of FIG. 11A. FIGS. 12B, 12C, and 12D illustrate enlarged views respectively showing sections aa, bb, and cc of FIG. 12A. FIGS. 13B, 13C, and 13D illustrate enlarged views respectively showing sections aa, bb, and cc of FIG. 13A.

Referring to FIG. 7A, a first carrier substrate CR1 may be provided. A first semiconductor chip 100 and a second semiconductor chip 200 may be disposed on the first carrier substrate CR1.

The first carrier substrate CR1 may be a bulk silicon substrate such as a wafer. A first adhesion layer AD1 may be interposed between the first carrier substrate CR1 and the first and second semiconductor chips 100 and 200. The first adhesion layer AD1 may include a non-organic dielectric material, such as silicon oxide.

Referring to FIGS. 7A and 7B, the first semiconductor chip 100 may include a first preliminary semiconductor substrate 110P, a first circuit layer 120, and a first signal wiring layer 130. The first preliminary semiconductor substrate 110P may be a silicon substrate thicker than a first semiconductor substrate 110 which will be discussed below. The first circuit layer 120 and the first signal wiring layer 130 may be disposed on the first preliminary semiconductor substrate 110P.

Referring to FIGS. 7A and 7C, the second semiconductor chip 200 may include a second preliminary semiconductor substrate 210P, a second circuit layer 220, and a second signal wiring layer 230. The second preliminary semiconductor substrate 210P may be a silicon substrate thicker than a second semiconductor substrate 210 which will be discussed below. The second circuit layer 220 and the second signal wiring layer 230 may be disposed on the second preliminary semiconductor substrate 210P.

Referring to FIGS. 7A and 7D, a gap GAP may be present between the first preliminary semiconductor substrate 110P and the second preliminary semiconductor substrate 210P.

Referring to FIGS. 8A and 8B, a dielectric pattern 910 may be formed to fill the gap GAP between the first preliminary semiconductor substrate 110P and the second preliminary semiconductor substrate 210P. The dielectric pattern 910 may cover a lateral surface of the first semiconductor chip 100 and a lateral surface of the second semiconductor chip 200. The dielectric pattern 910 may be formed by, for example, a deposition process.

Referring to FIGS. 9A and 9B, a direct bonding may be employed to directly bond a third semiconductor chip 300 to the first semiconductor chip 100 without using an adhesion layer. The first signal wiring layer 130 may be in contact with a first unified wiring layer 330. For example, first signal lines 134t may be in contact with the first unified lines 332b, and a first upper dielectric layer 131 may be in contact with a first lower dielectric layer 331.

Referring to FIGS. 9A and 9C, a chip stack structure ST may be disposed on the second semiconductor chip 200. A direct bonding may be employed to directly bond a fourth semiconductor chip 400 to the second semiconductor chip 200. The second signal wiring layer 230 may be in contact with a second unified wiring layer 430. For example, second signal lines 234t may be in contact with the second unified lines 432b, and a second upper dielectric layer 231 may be in contact with a second lower dielectric layer 431.

Referring to FIGS. 9A and 9D, a direct bonding may be employed to directly bond a connection die 500 to the first semiconductor chip 100 and the second semiconductor chip 200. The first signal wiring layer 130 and the second signal wiring layer 230 may be disposed in contact with a third signal wiring layer 520. For example, the first signal lines 134t and the second signal lines 234t may be in contact with the third signal lines 522b. The first upper dielectric layer 131 and the second upper dielectric layer 231 may be in contact with a third lower dielectric layer 521.

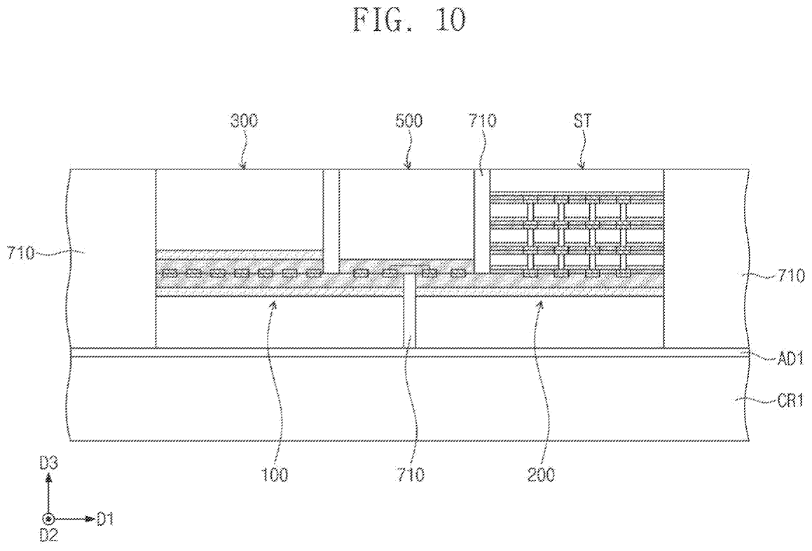

Referring to FIGS. 9A and 10, a dielectric material may be deposited on the dielectric pattern 910 to form a dielectric structure 710. The dielectric material may include a non-organic dielectric material, such as silicon oxide. The dielectric structure 710 may be formed by, for example, a deposition process. The dielectric structure 710 may cover a lateral surface of the third semiconductor chip 300, a lateral surface of the fourth semiconductor chip 400, and a lateral surface of the connection die 500. The dielectric structure 710 may fill a space between the third semiconductor chip 300 and the connection die 500 and between the fourth semiconductor chip 400 and the connection die 500.

Referring to FIGS. 10 and 11A, a second carrier substrate CR2 may be disposed on the third semiconductor chip 300, an uppermost fourth semiconductor chip 400t of the chip stack structure ST, the connection die 500, and the dielectric structure 710. A second adhesion layer AD2 may be interposed between the second carrier substrate CR2 and the third semiconductor chip 300, the fourth semiconductor chip 400t, the connection die 500, and the dielectric structure 710.

Afterwards, the first carrier substrate CR1 may be turned upside down. The first carrier substrate CR1 and the first adhesion layer AD1 may be removed. For example, an etching process may be performed to remove the first carrier substrate CR1 and the first adhesion layer AD1.

As shown in FIGS. 11A to 11D, additionally, thicknesses of the first preliminary semiconductor substrate 110P and the second preliminary semiconductor substrate 210P may be reduced to form a first semiconductor substrate 110 and a second semiconductor substrate 210. The thickness reduction process may include a grinding process.

Referring to FIGS. 12A and 12B, a first through hole may be formed to expose a buried first power rail 124, and a second through hole may be formed to expose a buried second power rail 224. A first through via 111 may be formed to contact the buried first power rail 124. A second through via 211 may be formed to contact the buried second power rail 224. The formation of the first through via 111 and the second through via 211 may include forming a barrier layer, forming a conductive layer on the barrier layer, and patterning the barrier layer and the conductive layer.

Referring to FIGS. 13A to 13D, a power distribution wiring layer 600 may be formed on a second surface 110b of the first semiconductor substrate 110, a fourth surface 210b of the second semiconductor substrate 210, and the dielectric structure 710. A first power distribution line 621 may be formed to connect with the first through via 111. A second power distribution line 622 may be formed to connect with the second through via 211. A connection pad 640 and a connection terminal 680 may be sequentially formed on the power distribution lines 621 and 622.

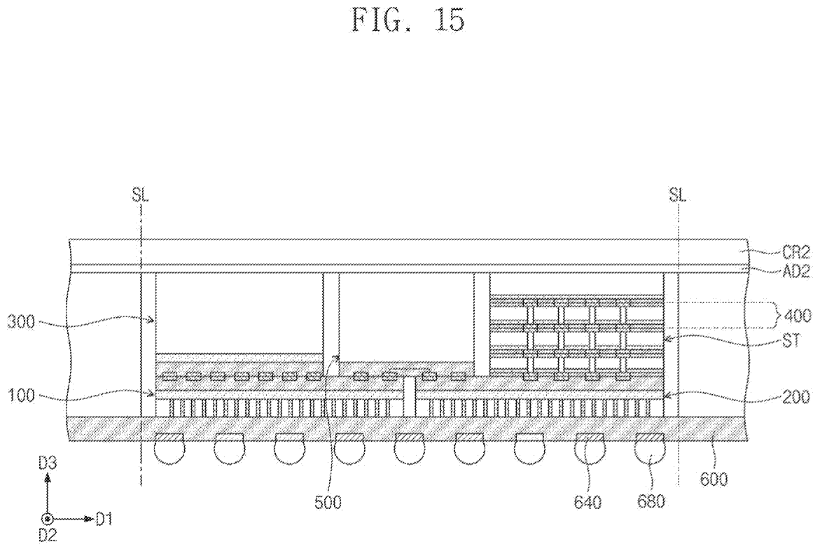

Referring to FIG. 14, the second carrier substrate CR2 may be turned upside down. Afterwards, a thickness of the second carrier substrate CR2 may be reduced by a process such as grinding. Referring to FIG. 15, the second carrier substrate CR2, the second adhesion layer AD2, and the power distribution wiring layer 600 may be diced along a sawing line SL. The sawing line SL may be designed to be spaced apart in a first direction D1 and a second direction D2 from the first, second, third, and fourth semiconductor substrates 110, 210, 310, and 410. As a result, even after the sawing process, the dielectric structure 710 may remain on a lateral surface of each of the first, second, third, and fourth semiconductor substrates 110, 210, 310, and 410, thereby protecting the first, second, third, and fourth semiconductor substrates 110, 210, 310, and 410. The second carrier substrate CR2 and the second adhesion layer AD2 may be diced to form a thermal radiation structure 720 and an adhesion pattern 730. In conclusion, a semiconductor package 1000 may be formed as shown in FIG. 2.

According to the disclosure, a series of processes may be performed to form a semiconductor package (e.g., system in package (SIP)) in a single fabrication line. This procedure may increase process stability, compared to a case in which a plurality of chips are individually formed in different fabrication lines and then are bonded to an interposer. As a result, it may be possible to increase process reliability of semiconductor packages.

In a semiconductor package according to one or more embodiments of the disclosure, each of different kinds of logic chips may include on a front surface thereof a plurality of signal lines configured to route signals, and may also include a plurality of power distribution lines on a front surface thereof. In addition, a hybrid bonding may be employed such that a connection die for connecting the logic chips may be bonded to the front surfaces of the logic chips. As a result, a minimum input/output (I/O) path may be provided between the logic chips, and accordingly, signals may be satisfactorily transferred between the logic chips and the semiconductor package may have increased reliability.

This detailed description of the disclosure should not be construed as limited to the embodiments set forth herein, and it is intended that the disclosure cover the various combinations, the modifications and variations of the disclosure without departing from the spirit and scope of the disclosure.

What is claimed is:

1. A semiconductor package comprising:
a first semiconductor chip;
a second semiconductor chip spaced apart from the first semiconductor chip in a first direction; and
a connection die on the first semiconductor chip and the second semiconductor chip,
wherein a hybrid bonding is established between the connection die and the first semiconductor chip and between the connection die and the second semiconductor chip,
wherein the first semiconductor chip comprises a first semiconductor substrate comprising a first surface and a second surface,
wherein the first surface and the second surface are on opposite sides of the first semiconductor substrate, and wherein the first surface is closer than the second surface to the connection die,
wherein the second semiconductor chip comprises a second semiconductor substrate having a third surface and a fourth surface,
wherein the third surface and the fourth surface are on opposite sides of the second semiconductor substrate, and wherein the third surface is closer than the fourth surface to the connection die, and
wherein the first semiconductor chip and the second semiconductor chip further comprise a power distribution wiring layer disposed on the second surface of the first semiconductor chip and the fourth surface of the second semiconductor substrate.

2. The semiconductor package of claim 1,
wherein the power distribution wiring layer comprises:
a dielectric layer;
a plurality of first power distribution lines in the dielectric layer; and
a plurality of second power distribution lines in the dielectric layer,
wherein the dielectric layer is in contact with the first semiconductor substrate and the second semiconductor substrate.

3. The semiconductor package of claim 2, wherein the dielectric layer comprises a non-organic dielectric material.

4. The semiconductor package of claim 3, wherein the non-organic dielectric material comprises silicon oxide (SiO₂).

5. The semiconductor package of claim 1,
wherein the first semiconductor chip further comprises:
a first circuit layer disposed on the first surface of the first semiconductor substrate;
a first signal wiring layer disposed on the first circuit layer; and
a first through electrode that penetrates the first semiconductor substrate, and
wherein the second semiconductor chip further comprises:
a second circuit layer disposed on the third surface of the second semiconductor substrate;
a second signal wiring layer disposed on the second circuit layer; and
a second through electrode that penetrates the second semiconductor substrate.

6. The semiconductor package of claim 5, wherein the connection die comprises:
a third semiconductor substrate; and
a connection wiring layer disposed on the third semiconductor substrate,
wherein the connection wiring layer is connected to the first signal wiring layer and the second signal wiring layer.

7. The semiconductor package of claim 1, further comprising:
a third semiconductor chip disposed on the first semiconductor chip; and
a fourth semiconductor chip disposed on the second semiconductor chip,
wherein the third semiconductor chip and the fourth semiconductor chip are spaced apart in the first direction and are disposed on opposites sides of the connection die,
wherein a hybrid bonding is established between the third semiconductor chip and the first semiconductor chip, and
wherein a hybrid bonding is established between the fourth semiconductor chip and the second semiconductor chip.

8. The semiconductor package of claim 7, further comprising:
a plurality of fourth semiconductor chips which includes the fourth semiconductor chip,
wherein the plurality of fourth semiconductor chips are stacked on the second semiconductor chip, and
wherein each of the plurality of fourth semiconductor chips comprises a through electrode.

9. The semiconductor package of claim 7, wherein
each of the first semiconductor chip and the second semiconductor chip are logic chips, and
each of the third semiconductor chip and the fourth semiconductor chip are a dummy chip or a memory chip.

10. The semiconductor package of claim 7, further comprising a thermal radiation structure disposed on the connection die, the third semiconductor chip, and the fourth semiconductor chip.

11. The semiconductor package of claim 7, wherein
the first semiconductor chip has a first width in the first direction,
the second semiconductor chip has a second width in the first direction,
the third semiconductor chip has a third width in the first direction,
the fourth semiconductor chip has a fourth width in the first direction,
the first width is greater than the third width, and
the second width is greater than the fourth width.

12. The semiconductor package of claim 1, wherein the connection die does not include a transistor.

13. The semiconductor package of claim 1, further comprising a dielectric structure that covers a lateral surface of the first semiconductor chip, a lateral surface of the second semiconductor chip, a top surface of the first semiconductor chip, and a top surface of the second semiconductor chip,
wherein the top surface of each of the first semiconductor chip and the second semiconductor chip are exposed to the connection die, and
wherein the dielectric structure includes a non-organic dielectric material.

14. The semiconductor package of claim 1, wherein, when viewed in plan, the power distribution wiring layer vertically overlaps a region between the first semiconductor substrate and the second semiconductor substrate.

15. A semiconductor package, comprising:
a first semiconductor chip and a second semiconductor chip that are spaced apart from each other in a first direction; and
a connection die disposed on the first semiconductor chip and the second semiconductor chip,
wherein the first semiconductor chip comprises:
a first semiconductor substrate having a first surface and a second surface, wherein the first surface and the second surface are on opposites sides of the first semiconductor substrate, and wherein the first surface is closer than the second surface to the connection die;
a first wiring layer disposed on the first surface; and
a first through via that penetrates the first semiconductor substrate from the second surface toward the first surface,
wherein the second semiconductor chip comprises:
a second semiconductor substrate having a third surface and a fourth surface, wherein the third surface and the fourth surface are on opposite sides of the second semiconductor substrate, and wherein the third surface is closer than the fourth surface to the connection die;
a second wiring layer disposed on the third surface; and
a second through via that penetrates the second semiconductor substrate from the fourth surface toward the third surface,
wherein the first semiconductor chip and the second semiconductor chip further comprise a power distribution wiring layer disposed on the second surface of the first semiconductor substrate and the fourth surface of the second semiconductor substrate, and
wherein the power distribution wiring layer comprises:
a common dielectric layer in contact with the second surface of the first semiconductor substrate and the fourth surface of the second semiconductor substrate;
a first power distribution line connected to the first through via; and
a second power distribution line connected to the second through via.

16. The semiconductor package of claim 15, wherein
the first semiconductor chip further comprises a buried first power rail on the first surface,
the second semiconductor chip further comprises a buried second power rail on the third surface,
the buried first power rail is connected to the first through via, and
the buried second power rail is connected to the second through via.

17. The semiconductor package of claim 15, further comprising a dielectric structure that covers a lateral surface of the first semiconductor chip, a lateral surface of the second semiconductor chip, a top surface of the first semiconductor chip, and a top surface of the second semiconductor chip,
wherein the top surface of each of the first semiconductor chip and the second semiconductor chip are exposed to the connection die, and
wherein the dielectric structure includes a non-organic dielectric material.

18. The semiconductor package of claim 15, further comprising:
a third semiconductor chip disposed on the first semiconductor chip; and
a plurality of fourth semiconductor chips disposed on the second semiconductor chip,
wherein the third semiconductor chip and the plurality of fourth semiconductor chips are spaced apart in the first direction and are disposed on opposite sides of the connection die,
wherein a hybrid bonding is established between the third semiconductor chip and the first semiconductor chip,
wherein a hybrid bonding is established between the second semiconductor chip and a fourth semiconductor chip among the plurality of fourth semiconductor chips that is closest to the second semiconductor chip,
wherein a hybrid bonding is established between neighboring fourth semiconductor chips from among the plurality of fourth semiconductor chips,
wherein each of the first semiconductor chip and the second semiconductor chip are logic chips,
wherein the third semiconductor chip is a dummy chip or a memory chip, and
wherein each of the plurality of fourth semiconductor chips is a memory chip.

19. The semiconductor package of claim 18, wherein
at least one of the first semiconductor chip and the second semiconductor chip are provided in plural,
the connection die is provided in plural, and
at least one of a first semiconductor chip among the plurality of first semiconductor chips and a second semiconductor chip among the plurality of second semiconductor chips is connected to at least two connection dies from among the plurality of connection dies.

20. A semiconductor package comprising:
a first semiconductor chip;
a second semiconductor chip spaced apart in a first direction from the first semiconductor chip;
a third semiconductor chip disposed on the first semiconductor chip;
a plurality of fourth semiconductor chips stacked on the second semiconductor chip; and
a connection die disposed on the first semiconductor chip and the second semiconductor chip,
wherein the connection die is disposed between the third semiconductor chip and the plurality of fourth semiconductor chips,
wherein a hybrid bonding is established between the first semiconductor chip and the second semiconductor chip,
wherein the first semiconductor chip comprises:
a first semiconductor substrate comprising a first surface and a second surface, wherein the first surface and the second surface are on opposite sides of the first semiconductor substrate;
a first circuit layer disposed on the first surface;
a first signal wiring layer disposed on the first circuit layer; and
a first through via that penetrates the first semiconductor substrate,
wherein the second semiconductor chip comprises:
a second semiconductor substrate having a third surface and a fourth surface, wherein the third surface and the fourth surface are on opposite sides of the second semiconductor substrate;
a second circuit layer disposed on the fourth surface;
a second signal wiring layer disposed on the second circuit layer; and
a second through via that penetrates the second semiconductor substrate,
wherein the connection die comprises:
a third semiconductor substrate; and
a third signal wiring layer disposed on the third semiconductor substrate,
wherein the third signal wiring layer is in contact with the first signal wiring layer and the second signal wiring layer, and
wherein the first semiconductor chip and the second semiconductor chip further comprise a power distribution wiring layer disposed on the second surface of the first semiconductor chip and the fourth surface of the second semiconductor substrate.
